(19) United States
(12) Patent Application Publication
(10) Pub. No.: US 2025/0052803 A1
(43) Pub. Date: Feb. 13, 2025

(54) METHOD FOR MONITORING AN ENERGY SUPPLY TO A MOTOR VEHICLE

(71) Applicant: Robert Bosch GmbH, Stuttgart (DE)

(72) Inventors: Quang-Minh Le, Calw (DE); Juergen Motz, Steinheim An Der Murr (DE); Patrick Lueckel, Stuttgart (DE)

(21) Appl. No.: 18/710,877

(22) PCT Filed: Jan. 20, 2023
(86) PCT No.: PCT/EP2022/085119

§ 371 Date: May 16, 2024

(30) Foreign Application Priority Data
Feb. 8, 2022 (DE) 10 2022 201 267.4

(51) Int. Cl. G01R 31/00; G07C 5/08

(52) U.S. Cl. CPC G01R 31/007; G07C 5/0808

(57) ABSTRACT

A method for monitoring an energy supply of a motor vehicle. At least one supply path is provided, which supplies a safety-relevant, consumer with electrical energy. The supply path includes at least two parallel-connected current-carrying components, in particular a switch and/or fuse, protecting the consumer. At least one electrical characteristic variable, in particular a measure of an electrical resistance, describing the functionality of the supply path is ascertained. At least one electrical measured variable is sensed, which is applied to at least one of the components. As a function of the measured variable, the electrical characteristic variable (R) is determined. A check of at least the electrical characteristic variable takes place. The current-carrying components and the supply path are arranged at least partially in a control unit.

### FIELD

The present invention relates to a method for monitoring an energy store of a motor vehicle.

### BACKGROUND INFORMATION

German Patent Application No. DE 10 2018 212 369 A1 describes a method for monitoring an energy supply in a motor vehicle, wherein, in an on-board power subsystem, at least one energy store supplies energy to a plurality of preferably safety-relevant consumers, wherein at least one measured variable of an energy store and/or of at least one consumer is sensed, wherein at least one cable harness model is provided, which represents the on-board power subsystem, and wherein a parameter estimator is provided, which estimates at least one characteristic variable of the cable harness model using the measured variable.

An object of the invention is to provide a method that further increases the reliability of an energy supply. The object may be achieved by features of the present invention.

### SUMMARY

According to an example embodiment of the present invention, by monitoring the internal control unit power supply paths, in particular for safety-relevant consumers, the reliability of the energy supply can be further increased. In particular, the diagnostic coverage can be expanded to the entire energy supply path of the, in particular safety-relevant, consumer on the basis of the monitoring of the electrical resistances of the current-carrying paths and components, and preferably also of the connections thereof. Through the use of suitable measurement methods, such as differential voltage measuring amplifiers and corresponding calculation methods via parameter estimation methods, time-continuous and precise ascertainment of the internal control unit characteristic variables, such as resistances, is possible.

According to an example embodiment of the present invention, by using a parameter estimator to determine the electrical characteristic variable or the electrical resistance, large proportions of such measurement errors can be ruled out, which could manifest as both random and systematic error quantities during the measurement.

According to an example embodiment of the present invention, particularly preferably, an, in particular static, threshold value, for example a manufacturer-specified nominal value (for example, of the resistance) of the current-carrying component, can be used to ascertain error information. If the estimated characteristic variable of the component deviates greatly from its nominal value, this can be used as error information, for example by entering it into the error memory or passing the error information to a higher-level energy management system for further processing, for example as a driver warning or the degradation of the driving operation. This can further increase the safety in the vehicle.

According to an example embodiment of the present invention, particularly expediently, the described monitoring principle can be expanded to different circuit constellations, in particular of parallel circuits, even of different current-carrying components, in that suitable measuring points for current and voltage can be selected upstream of the branchings and/or at the start or end of the current paths, for example at the contacts. As a result, in addition to the resistance values of the current-carrying components, the resistances of the supply line and/or contacts can also be taken into account and used for ascertaining errors.

In an expedient development of the present invention, the threshold value is flexibly selected as a function of a resistance model. In particular, shifting of the operating points, for example due to changed temperature conditions, cannot lead to false triggers in this case. The safety of the arrangement is thereby further increased.

In an expedient development of the present invention, the currentness of the measured values is checked and, if necessary, a new ascertainment is initiated. Reliable and current statements regarding the functionality can thus be made.

Further expedient developments of the present invention arise from the disclosure herein.

### BRIEF DESCRIPTION OF THE DRAWINGS

FIG. 1 shows, by way of example, an exemplary embodiment of the power distributor connecting two on-board power subsystems, according to the present invention.

FIG. 2 shows the variables to be sensed in a parallel circuit of two current-carrying switching means, according to an example embodiment of the present invention.

FIG. 3 shows the variables to be sensed in a parallel circuit of two current-carrying fuses, according to an example embodiment of the present invention.

FIG. 4 shows the variables to be sensed in a parallel circuit of two current-carrying switching means and of two current-carrying fuses, according to an example embodiment of the present invention.

FIG. 5 shows a measuring arrangement for ascertaining the overall characteristic variable of the arrangement according to FIG. 4.

FIG. 6 shows a structure of the estimation method in the form of a Kalman filter, according to an example embodiment of the present invention.

FIG. 7 shows an arrangement for ascertaining a flexible threshold value, according to an example embodiment of the present invention.

FIG. 8 shows an expansion of the measuring arrangement according to FIG. 5, according to an example embodiment of the present invention.

FIG. 9 shows a perspective view of current-carrying parts of an internal control unit arrangement with associated structure of a further device for determining the overall characteristic variable of this arrangement, according to an example embodiment of the present invention.

FIG. 10 shows a structure of a further device for ascertaining a further expanded current path, according to an example embodiment of the present invention.

### DETAILED DESCRIPTION OF EXAMPLE EMBODIMENTS

The present invention is shown schematically on the basis of an exemplary embodiment and is described extensively below with reference to the figures.

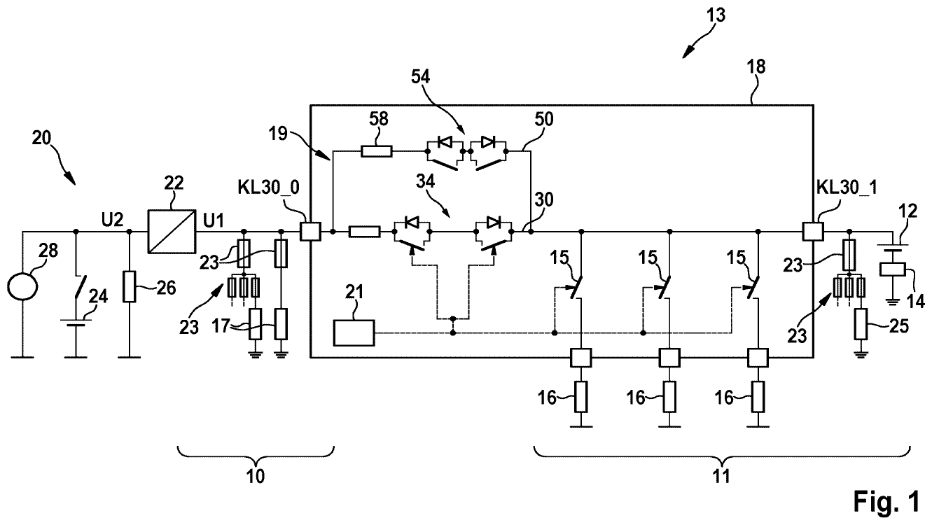

FIG. 1 shows a possible topology of an energy supply system consisting of an on-board power system 13, which comprises an energy store 12, in particular a battery 12 with an associated sensor 14, preferably a battery sensor, as well as a plurality of, in particular safety-relevant, consumers 16, which are protected or controlled by an electrical power distributor 18. The consumers 16 are special consumers with high requirements or a high need for protection, in general referred to as safety-relevant consumers 16. They are, for example, an electric steering and/or a brake system as components that must absolutely be supplied in order to ensure steering and/or braking of the vehicle in the event of a fault. Characteristic variables of the respective consumer 16 are sensed separately and, in the event of deviations from tolerable values, the respective switch 15 is opened. The on-board power system 13 consists of a safety-relevant on-board power subsystem 11 and a non-safety-relevant on-board power subsystem 10. The safety-relevant on-board power subsystem 11 can be separated from the non-safety-relevant on-board power subsystem 10 by the power distributor 18, in particular in the event of a fault or critical state of the non-safety-relevant on-board power subsystem 10. The safety-relevant on-board power subsystem 11 is, for example, an ASIL-qualified on-board power subsystem 11 (for example qualified according to DIN ISO26262), which comprises at least one of the safety-relevant consumers 16 and, where appropriate, can be equipped with its own energy store 12 for voltage support. The non-safety-relevant on-board power subsystem 10 comprises at least one non-safety-relevant consumer 17, which may, for example, be so-called QM consumers. However, it is not ruled out here that at least one further safety-relevant consumer can also be arranged in the non-safety-relevant on-board power subsystem 10, for example in a redundant design of the safety-relevant consumers. The non-safety-relevant on-board power subsystem 10 is a non-ASIL-qualified on-board power system.

The energy store 12 is likewise connected to a terminal (terminal KL30_1) of the power distributor 18. The sensor 14 is able to sense an electrical characteristic variable, such as a voltage Ub at the energy store 12 and/or a current Ib through the energy store 12 and/or a temperature Tb of the energy store 12. The sensor 14 can, for example, ascertain the state of charge SOC of the energy store 12 or further characteristic variables of the energy store 12 from the ascertained electrical characteristic variables Ub, Ib, Tb. A further supply branch for at least one further consumer 25 is optionally also provided at the further terminal (KL 30_1) of the power distributor 18 to which the energy store 12 is also connected. The consumer 25 is, by way of example, protected via a fuse 23. Still further consumers 25 may be provided, which can likewise be protected via fuses 23. These consumers 25 are consumers that are still to be supplied with energy by the energy store 12 even if the switching means 19 in the power distributor 18 is disconnected or opened, preferably safety-critical consumers 25 that are critical with regard to malfunctions with respect to the supply security. An (optional) safety-relevant or safety-critical on-board power system path or on-board power subsystem 11 is thus connected to the terminal KL 30_1.

The power distributor 18 is able to ascertain corresponding characteristic variables such as voltage Uv, current Iv of the consumers 16. In addition, the power distributor 18 is also able to ascertain corresponding characteristic variables of the energy store 12 such as voltage Ub and/or current Ib and/or temperature Tb. For this purpose, the power distributor 18 contains the corresponding sensors or receives the data from the sensor 14. The power distributor 18 also has corresponding evaluation means 21, such as a microcontroller, for storing or evaluating sensed variables. The evaluation means 21 is used to ascertain critical states, in particular of the safety-relevant on-board power subsystem 11, for example to recognize an overcurrent and/or an undervoltage or overvoltage at the on-board power subsystem 11 for the safety-relevant consumer 16, 25. For this purpose, corresponding characteristic variables are sensed and compared to suitable threshold values. For example, a microcontroller is used as the evaluation means 21. The microcontroller or the evaluation means 21 is also able to control corresponding switches 15 or the switching means 34 of a high-current-capable disconnector 34 in the main path 30 or a switching means 54 in an additional path 50. The additional path 50 is connected in parallel with the main path 30. The additional path 50 comprises the switching means 54 and a resistor 58 arranged in series therewith, in particular the current limiting resistor 58. In normal operation, both paths 30, 50 are active in parallel, i.e., their switching means 34, 54 are closed. In addition, the additional path 50 is used to pre-charge the non-safety-relevant on-board power subsystem 10 if, for example, an energy store is connected to the safety-relevant on-board power subsystem 11 for the first time. The capacitive portion of the non-safety-relevant on-board power subsystem 10 provides a high charging current via the additional path 50, which in this scenario must likewise be protected from overload.

A corresponding disconnecting or coupling function, in particular of the two on-board power system branches (on-board power subsystem 10 for non-safety-relevant consumers 17 at terminal KL 30_0; further on-board power subsystem 11 for safety-relevant consumers 16, 25) can be realized via the switching means 34. This serves in particular as a safety function for preventing the effects of critical states such as overvoltages or undervoltages and/or overcurrents and/or thermal overload. In the event of a fault, the two on-board power subsystems 10, 11 can be separated from one another by means of the power distributor 18 by opening the switching means 34, 54.

The on-board power system 13 has a lower voltage level U1 than an optionally provided high-voltage on-board power system 20, it may, for example, be a 14 V on-board power system. A DC voltage transformer 22 is arranged between the on-board power system 13 and the high-voltage on-board power system 20. The high-voltage on-board power system 20 comprises, by way of example, an energy store 24, for example a high-voltage battery, possibly with an integrated battery management system, a load 26 shown by way of example, for example a comfort consumer, such as an air-conditioning system, etc., supplied at an increased voltage level, as well as an electric machine 28. In this context, a voltage level U2 that is higher than the voltage level U1 of the basic on-board power system 13 is understood to be high-voltage. It could be a 48 volts on-board power system, for example. Alternatively, especially in vehicles with an electric drive, it could be even higher voltage levels. Alternatively, the high-volt on-board power system 20 could be eliminated entirely.

By way of example, a battery or accumulator is described as a possible energy store 12, 24 in the description. However, alternatively, other energy stores, for example on an inductive or capacitive basis, fuel cells, capacitors, or the like, suitable for this task can be used equally.

Particularly preferably, the switching means 34, 54 are each formed by at least two anti-serial-connected switching elements (connected in series with one another and oppositely, for example “back-to-back” or with a common source terminal), preferably using power semiconductors, particularly preferably FETs or MOSFETs. Instead of MOSFETs, relays, bipolar transistors or IGBTs with parallel diodes, etc. can also be used, for example.

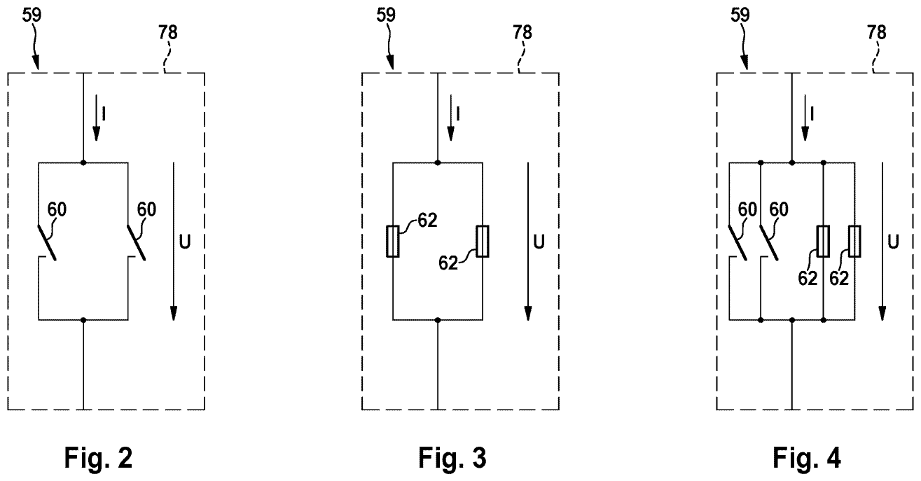

By the actions described below in connection with FIGS. 2-10, the diagnostic coverage level of the complete energy supply path 59 can be increased by monitoring in particular the internal connection and supply paths 59 within a control unit 78. The basic idea of internal monitoring of internal control unit supply paths 59 and connections is based on monitoring an electrical characteristic variable, in particular an electrical resistance R of the internal control unit current-carrying paths and components 60, 62, as well as connections or contacts 74. By using suitable measurement methods, such as differential voltage amplifiers or measuring amplifiers 66, and corresponding calculation methods, such as parameter estimation methods, realized in a parameter estimator 68, a time-continuous, precise ascertainment of the internal control unit resistances R as an electrical characteristic variable is possible.

In the exemplary embodiments shown below, a diagnosis takes place in two steps. First, the electrical characteristic variable, such as the electrical resistance R of components and current paths, is ascertained on the basis of the measured variables U, I (as a measure of the current I flowing through the component or as a measure of the voltage U dropping at the component) and by using parameter estimation methods. Subsequently, the results are evaluated and, if needed, subsequent system responses are initiated.

With reference to FIGS. 2 and 3, a diagnosis of the electrical property of a current-carrying element, such as a switching means 60 (FIG. 2), for example a transistor, particularly preferably a MOSFET, or a fuse 62 (FIG. 3) is shown as a first application. A current I flows through the current-carrying element 60, 62. A voltage U drops at the current-carrying element 60, 62. The determination of the resistances R of the current-carrying elements or components 60, 62 requires the measurement of the electrical differential voltage U, which is applied between the two component terminals or across the components. The supply path 59 is comprised of two parallel-connected subpaths, which are at least partially arranged in the control unit 78 and comprise corresponding current-carrying components 60, 62, such as switching means 60 or fuses 62, protecting the safety-relevant consumer 16, 25. Redundant hardware is sometimes used in highly safety-relevant applications so that, if a part of the system fails, the entire operation can still be maintained by means of the redundant design. This is shown by way of example in FIGS. 2 and 3 by corresponding parallel-connected switching means 60 (FIG. 2) or fuses 62 (FIG. 3). In principle, the method can also be used for the constellations according to FIG. 2 or 3. In practice, there are further combinations of two or more parallel-connected switching means 60 and/or of two or more parallel-connected fuses 62 so that a constellation according to FIG. 4 results by way of example. Here, at least, by way of example, two switching means 60 and at least two fuses 62 are in each case connected in parallel with one another. In this exemplary embodiment, the supply path 59, which is arranged at least partially in the control unit 78, comprises four parallel and thus redundant subbranches. They are fed by a current I, as flows upstream of the parallel branches. At the current-carrying components, such as the switching means 60 or fuses 62, protecting the safety-relevant consumers 16, 25, a voltage U drops.

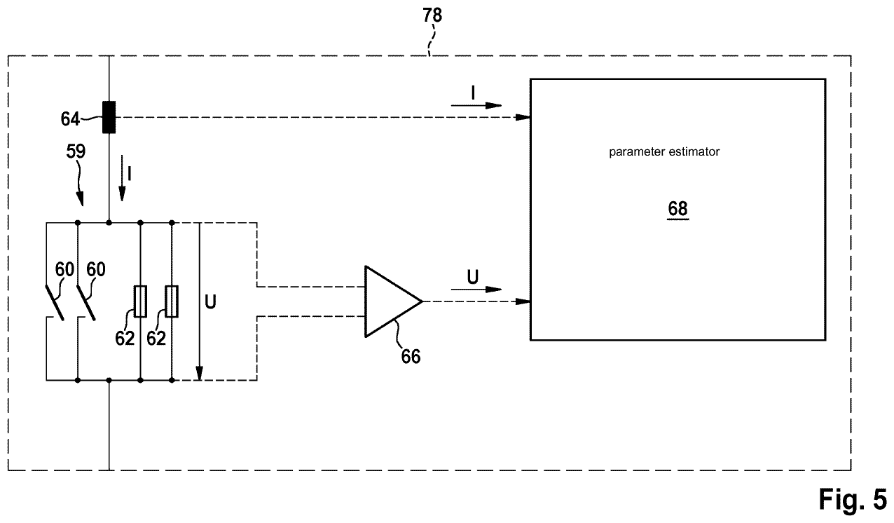

As FIG. 5 shows by way of example for the constellation according to FIG. 4, the measurement of the differential voltage U takes place by using a suitable voltmeter, such as a differential amplifier 66. The current I is measured by a corresponding measuring device, such as a measuring resistor 64 or measuring shunt. The output variables of the measuring resistor 64 as a measure of the flowing current I as well as of the differential amplifier 66 as a measure of the voltage U are supplied to the parameter estimator 68. The parameter estimator 68 is used to determine the electrical characteristic variable such as the resulting resistance R of the current-carrying component 60, 62, in particular excluding a large proportion of the measurement errors, which can manifest as both random and systematic error quantities during the measurement.

If all MOSFETs 60 and fuses 62 of the parallel construct are intact in operation, the entire current I flows through all four components 60, 62. The total conductance G of this construct can be formed as the sum of the electrical conductances of the four components 60, 62. If the conductance of at least one of the components 60, 62 deteriorates or, in the worst case scenario, if the connection (e.g., soldering joint) to the printed circuit board detaches, this is reflected directly in the conductance G or in the resistance R of the entire construct or supply path 59. The total conductance G becomes lower; the total resistance R becomes larger. As a simple example: Assuming that all components 60, 62 have the same resistance value in nominal operation, the failure of one of the four parallel-connected components 60, 62 increases the total resistance by approximately 33% with respect to the original total resistance R.

If the total resistance R is constantly monitored over the course of operation by means of measured variables U, I and a resistance observer or parameter estimator 68, the failure of one of the four components 60, 62 becomes immediately noticeable on the basis of a change in the total resistance R. This error, which is considered latent, can thus be detected. A deterioration of the resistance R can in principle also be recognized, provided that sufficient current excitation is present. FIG. 5 shows the structure of such a device for ascertaining the resistance R.

If the change in the estimated resistance R of the construct according to FIG. 4 exceeds a certain limit value Rg, this can be registered as an error, whereupon corresponding responses can be triggered (e.g., entry into the error memory or passing of the error information to a higher-level energy management system for further processing, for example driver warning or degradation of the driving operation).

Even in the event that there is no component failure, but the electrical conductivity G of the individual components (switching means 60 and/or fuse 62) deteriorates, this can also be considered a latent error since this deterioration is also reflected in the total resistance R.

The equivalent resistance of the parallel construct is now denoted by R. The resistance R is the corresponding characteristic variable of this network model, which is quite simple in the main application, and is combined in a parameter vector xₖ below.

Existing voltage measurements and current measurements are drawn in the above equivalent circuit diagram as U, I and, where appropriate, are referred to as U_{FET+FUSE} (or U_{D} as differential voltage) or I_{FET+FUSE} in the following formulas.

The following equation results, which describes the network model according to Ohm's law:

$${U}_{D} = I \cdot R$$

The equation can be described in the form of the characteristic variable of interest, namely, the resistance R, as a parameter vector xₖ. The parameter vector xₖ can thus be updated for each new time step, using the parameter estimator 68 drawing on corresponding measured values, which are combined in the measurement vector zₖ.

The corresponding variables are combined below in corresponding vectors or matrices, as already described:

xₖ=[R], Parameter vector:

f(\hat{x}ₖ₋₁,uₖ)=\hat{x}ₖ₋₁, System equation:

zₖ=[U_{D}] Measurement vector:

h(\hat{x}ₖ⁻,0)=[U_{D}−I·R] Residual:

In the exemplary embodiment, a so-called extended Kalman filter (EKF), as a parameter estimator 68, is used to recursively solve the equation system. Alternatively, further parameter estimators 68 could also be used, such as (recursive) least square methods, or further state estimators such as standard/unscented Kalman filters, particle filters, or similar estimation/optimization methods.

### Online Estimation and Compensation of Systematic Measurement Errors:

In principle, measurement errors, i.e., errors in the actual measurement operation, are composed of systematic (epistemic) and random (aleatory) errors. The latter originate from random physical processes and cannot be influenced without a change in the physical measurement principle. Systematic errors, however, are based on deterministic relationships. If these relationships can now be estimated online, i.e., in operation, this error source can be eliminated.

To this end, the previous estimation model can be expanded by a so-called interference model. The interference model describes the influence of unknown states on the measurement result, here the systematic measurement error. In order to compensate for the systematic measurement error, these unknown parameters must be estimated in addition to the resistances. This is possible with sufficient measuring points (observability). A common model for systematic measurement errors in practice is the linear correlation

$$\hat{m} = a \cdot m + b .$$

Here, m is the physical variable to be measured, e.g., current I or voltage U. Accordingly, \hat{m} is the generally deviating measurement. The parameters a, b correspond to amplification and bias (constant superimposed variable). A perfect sensor would be provided at a=1, b=0. If a, b can now be estimated (also referred to as calibration), the systematic measurement error can be compensated.

In general, there are usually a plurality of sensors and corresponding systematic measurement errors. However, only the cumulative influence of these errors on the estimation of the resistances is relevant to the estimation of the resistances. The additional parameters to be estimated can therefore be greatly reduced, which usually makes calibration possible in the first place. In the estimation of the equivalent resistance of the parallel construct and corresponding measuring points, the voltage U_{D} results as

$${U}_{D} = {I}_{FET + FUSE} R .$$

If the above model is now assumed for the systematic measurement errors, the result is

$$\begin{matrix}{U}_{1} = ( {a}_{1} {I}_{FET + FUSE} + {b}_{1} ) R \\ = {a}_{1} {I}_{FET + FUSE} R + {\underbrace{( {b}_{1} R )}}_{{\hat{b}}_{1}}\end{matrix}$$

Instead of the bias b₁, the bias \hat{b}₁ must thus be estimated in order to compensate for the bias error. The same is possible for the amplification error depending on the availability of measuring points. The same procedure applies here. In addition, a combination of the two calibration approaches is possible, provided that suitable excitations are present.

Furthermore, the estimation of the systematic measurement error can be used to diagnose the measuring points and to recognize them as faulty in the case of large errors. This additional information can be elemental for a sufficient ASIL qualification, which also includes the diagnosability of the measuring points.

If an estimation method is used that also takes into account random measurement errors, the measurement equation can be expanded by random variables ϵ, for example to

\hat{m}=(a·m+b)+ϵ.

The adjustment of the parameter estimation can take place by incorporating the further parameters into h(\hat{x}ₖ⁻, 0) and \hat{x}ₖ.

The estimation method, e.g., a Kalman filter, in this case provides an estimate of the resistances R as far as possible and the possibly cumulated parameters of the measurement equations with minimum variance, i.e., with the greatest possible estimation quality.

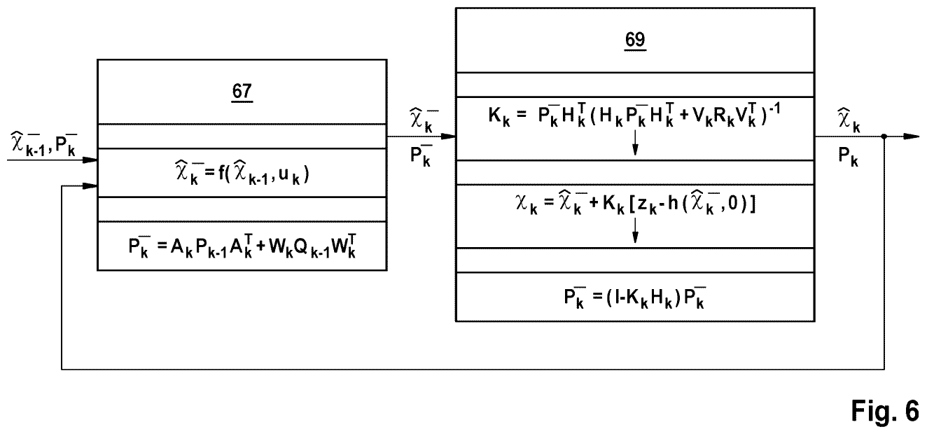

The structure of the Kalman filter as an essential part of the parameter estimator 68 is shown in FIG. 6. The parameter estimator 68 comprises at least one prediction 67 or time update. An initial estimate \hat{x}ₖ₋₁, the state variable xk, and an initial estimate Pk−1 of the error covariance Pk arrive as input variables at the prediction 67. In addition, in the steady state, the currently ascertained output values from a correction 69 (or measurement update), namely, the current parameter vector xk and the current error covariance Pk, arrive as input variables at the prediction 67.

In the prediction 67, an update or a time update takes place. In this case, a state prediction of the state variable xₖ takes place in the form of the equation

$${\hat{x}}_{k}^{-} = f ( {\hat{x}}_{k - 1} , {u}_{k} )$$

In addition, in the prediction 67, the error covariance matrix Pk is predicted in the form of the equation

$${P}_{k}^{-} = {A}_{k} {P}_{k - 1} {A}_{k}^{T} + {W}_{k} {Q}_{k - 1} {W}_{k}^{T}$$

where
Ak: Jacobian matrix of f(\hat{x}ₖ₋₁, uₖ)
Wk: system matrix of the system noise
Qk−1: variance of the system noise

The output variables \hat{x}ₖ⁻ and Pₖ⁻ arrive as input variables at block correction 69. In the correction 69, the estimated values are updated on the basis of the measurement(s). First, the so-called Kalman gain Kₖ is calculated with the formula

$${K}_{k} = {P}_{k}^{-} {{H}_{k}^{T} ( {H}_{k} {P}_{k}^{-} {H}_{k}^{T} + {V}_{k} {R}_{k} {V}_{k}^{T} )}^{- 1}$$

where
Hk: Jacobian matrix of h(\hat{x}ₖ⁻, 0)
Vk: system matrix of the measurement noise

Subsequently, in the correction 69, the estimation update takes place on the basis of the measurement according to the formula:

$${\hat{x}}_{k} = {\hat{x}}_{k}^{-} + {K}_{k} [ {z}_{k} - h ( {\hat{x}}_{k}^{-} , 0 ) ]$$

Lastly, in the correction, an update of the error covariance Pk takes place according to the formula:

$${P}_{k} = ( I - {K}_{k} {H}_{k} ) {P}_{k}^{-}$$

where I corresponds to the unit matrix.

The expected value and the covariance of the characteristic variables \hat{x}ₖ are thus estimated. In a first step of the filtering operation, the temporally preceding estimate is subjected to the state dynamics in order to obtain a prediction for the current time point. The predictions are corrected in block correction 69 with the new information of the current measured values and result in the sought current estimate.

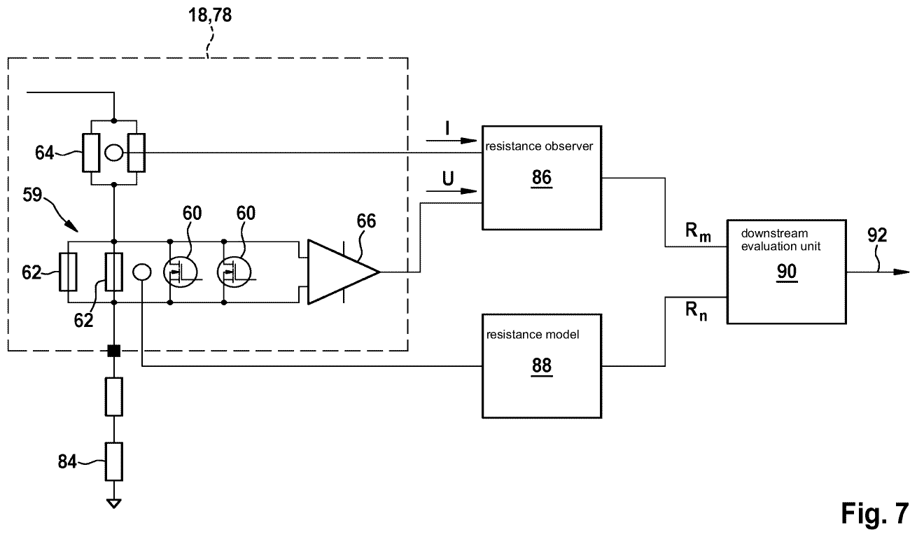

In FIG. 7, an approach for ascertaining the threshold value Rn is described. In the preceding exemplary embodiments, a threshold value of the maximum resistance Rn was used to evaluate the results. This nominal value can, for example, be derived from the specifications of the components 60, 62 or by means of existing knowledge or experience of the function development. The threshold value Rn may have a fixed value; the threshold value Rn may alternatively be designed as a computational model. The computational model can adjust the threshold value Rn accordingly depending on the current operating point. In order to ascertain the current operating point, further external influences, such as temperature T or the like, can be taken into account.

This is shown by way of example in FIG. 7. A resistance observer 86 ascertains, on the basis of the measured variables for voltage U and current I, the current resistance Rm of the parallel-connected switching means 60 and/or fuses 62. By way of example, two parallel circuits each of switching means 60 and fuses 62 are provided, as current-carrying components protecting the safety-relevant consumer 16, 25, in the load distributor 18, with the associated supply path 59 in the control unit 78. In parallel, the nominal resistance Rn or threshold value Rn is calculated online on the basis of a resistance model 88. By way of example, the resistance model 88 is realized as a thermal model. The resistance model 88 ascertains the nominal resistance Rn on the basis of the measured component temperature T. The evaluation of the results takes place in a downstream evaluation unit 90 (hardware error monitoring). Error information 92 can be generated depending on the comparison of the output variable Rm (estimated resistance Rm) of the resistance observer 86 and the output variable Rn of the resistance model 88, the threshold value Rn. The corresponding error responses to this error information 92 could, for example, be made in an entry in an error memory or a passing of the error information 92 to a higher-level system, for example energy management system, for further processing, for example in the form of a driver warning or degradation of the driving operation. Furthermore, for debouncing or for avoiding incorrectly recognized errors, a debounce function is provided, which only reports an error 92 if, for example, the estimated resistance Rm exceeds the tolerance threshold a number of n times in succession.

As a simple example: Assuming that all components 60, 62 have the same resistance value in nominal operation, the failure of one of the four parallel-connected components 60, 62 increases the total resistance by approximately 33% with respect to the original total resistance.

In a further part of the system, the currentness of the ascertained resistance values Rm is monitored. The operational capability of the vehicle depends on whether the necessary test intervals of the control units 78 have been complied with. If a reliable value is not available for a long time, a reliable statement about the functionality cannot be made. This takes place by storing a counter reading in the non-volatile memory of the computing unit. The counter counts the defined test cycles (e.g., driving cycles or Kl15 on/off cycles) and takes a defined action if a limit value is exceeded.

The following actions are taken if no current resistance Rm is available:
Step 1: Make a request to the vehicle to generate a load pulse
Step 2: If the request is unsuccessful, generate driver message.

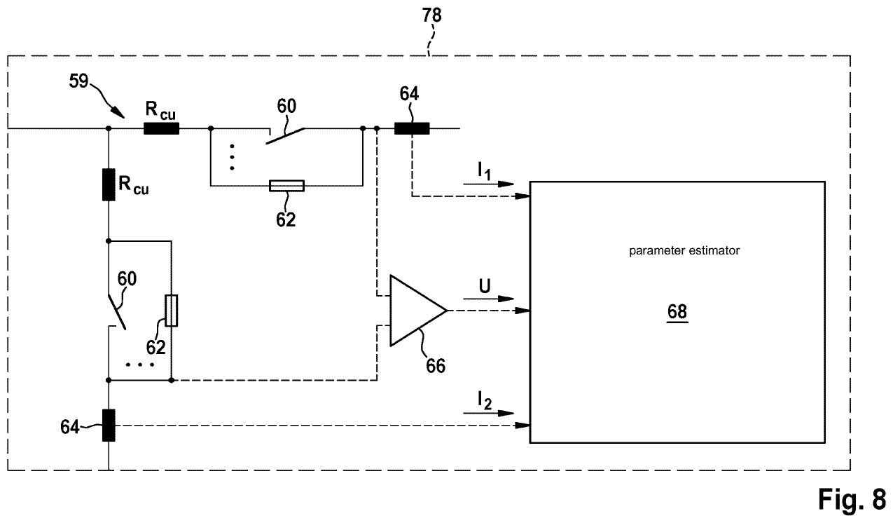

The exemplary embodiment according to FIG. 8 is understood as an expansion of the previous applications. The control units 78 very often include electrical networks, which can in principle be considered a merging of the previous arrangements. Parts of the printed circuit boards used in control units 78 can also be considered part of the current-carrying paths. If current measurements are available in the respective current paths, for example by means of measuring resistors 64, the resistance of the individual current paths including components (switching means 60 and/or fuse 62, also connected in parallel where appropriate) and copper busbar (line resistance R_{Cu}) can be determined by placing corresponding voltage measuring points.

FIG. 8 shows an example of a simple network consisting of two current paths that cross. Components such as switching means 60 and/or fuse 62, respectively connected in parallel, are in each branch. The total resistances R in the respective paths R1, R2 are respectively understood as the sum of all existing resistances in the current branches (total resistance R_{FET+FUSE} Of the current-carrying components 60, 62, of the busbar or printed circuit board busbar R_{Cu}). The components 60, 62 can be connected in parallel as often as desired, analogously to the described applications. A current measurement with associated measuring resistor 64 is present in each current branch. In addition to the voltage drop U, the respective current measured values I1, I2 are thus supplied to the parameter estimator 68 for ascertaining the respective total resistances R1, R2 in the individual current paths. Corresponding voltage measuring points for differential voltage measurement U via the measuring amplifier 66 are to be respectively provided as shown between the current-carrying components 60, 62 and respective measuring resistors 64. The principle can be used without limitations when the network becomes more complicated, for example by adding further current paths and further components such as switching means 60 and/or fuses 62. For star points with n-branchings and thus n strand resistances Rn, all strand resistances Rn can be monitored with n/2 differential voltage measuring amplifiers 66.

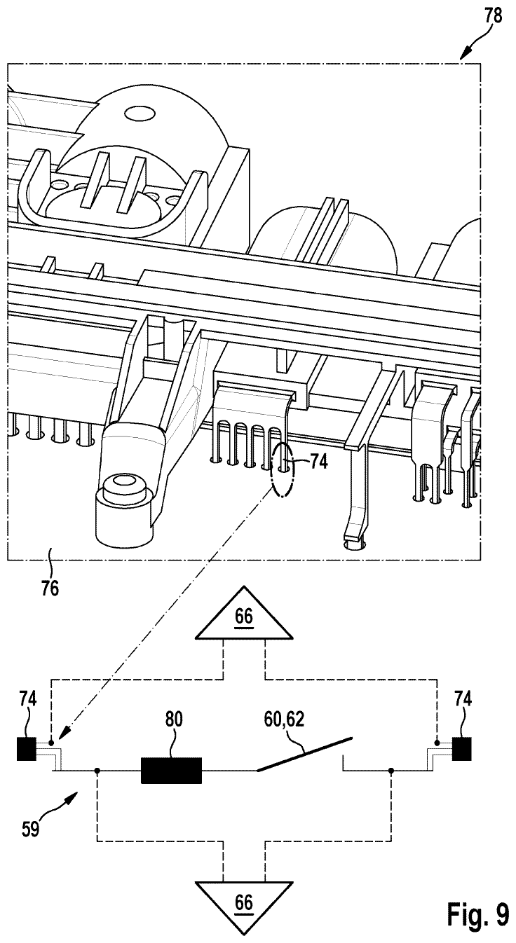

As indicated in FIG. 9, the entire supply path 59 comprises not only the current-carrying components 60, 62 and conductive paths but also contacts 74. These contacts serve as an interface to the outside world in the control unit 78 and connect the internal control unit supply paths 59 to the external cable harnesses. The contacts 74, for example plug contacts, are in principle connected, for example soldered or welded, to printed circuit boards 76, usually via a plurality of points or pins. Due to vehicle vibration or aging, these contacts 74 can deteriorate or even detach during the operating time. The ability to conduct current can thereby be severely affected. There is a potential latent error. Monitoring of the electrical contact properties of the contacts 74 is therefore of interest from a safety perspective.

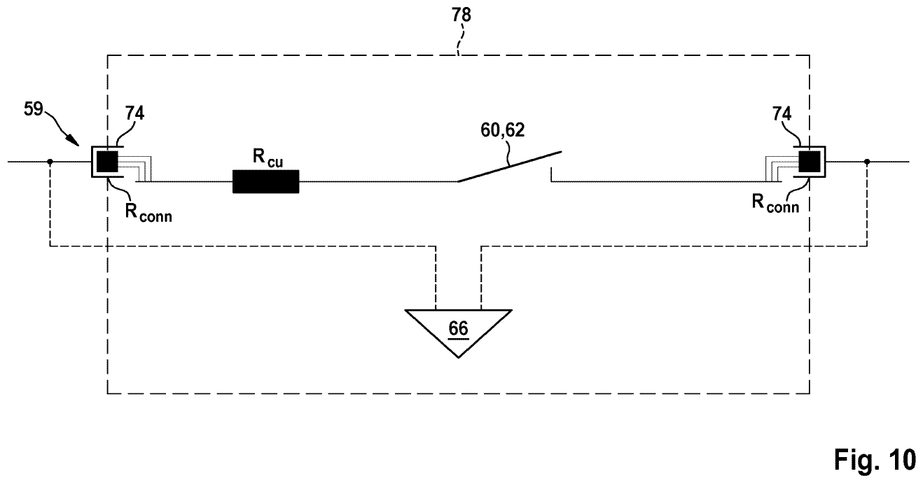

The measurement section or supply path 59, whose total resistance value R is monitored, can be expanded by suitably determining the differential voltage measuring points. If, as in FIG. 9 at the bottom, the voltage measuring points are no longer only positioned across the current-carrying components such as switching means 60 and/or fuse 62 but at the pins of the contacts 74 of the control unit 78 as shown in FIG. 10, the entire resistance R for the entire current path or supply path 59 including component 60, 62, conductive path (associated resistance R_{Cu}) and plug contact (associated resistance R_{conn}) can be monitored. To this end, a pin of the contact 74 is used as the sense line or voltage tap, while the other pins continue to have the task of conducting current.

If the sense lines or voltage taps are designed to be outside the control unit 78, the section to be monitored can be expanded even further. The monitored current path now consists of the current-carrying components such as switching means 60 and/or fuse 62, the conductive paths (R_{Cu}), and the entire plug contact system (R_{conn}) including mating connectors as shown in FIG. 10.

The power distributor 18 with associated monitoring circuit 34 is, for example, arranged in a 12 V on-board power system 13 in a motor vehicle, directly at the interface between the non-safety-relevant on-board power subsystem 10 and the safety-relevant on-board power subsystem 11, in particular ASIL-qualified on-board power subsystem 11. It comprises at least the disconnecting and connecting module, which consists of the main path 30 and the parallel-connected additional path 50 or supply path 59 with associated components 60, 62. However, the use is not limited thereto.

1-15. (canceled)

16. A method for monitoring an energy supply of a motor vehicle, wherein at least one supply path is provided, which supplies a safety-relevant consumer with electrical energy, wherein the supply path includes at least two parallel-connected current-carrying components protecting the consumer, the method comprising the following steps:
ascertaining at least one electrical characteristic variable, including a measure of an electrical resistance, describing a functionality of the supply path;
sensing at least one electrical measured variable, which is applied to at least one of the current-carrying components;
determining, as a function of the measured variable, the electrical characteristic variable; and
checking at least the electrical characteristic variable;
wherein the current-carrying components and the supply path are arranged at least partially in a control unit.

17. The method according to claim 16, wherein a measure of a voltage drop and a measure of a current flowing through the current-carrying components are sensed as a measured variable at the current-carrying components and the electrical characteristic variable, which includes a measure of a total resistance of the parallel-connected components, is ascertained from the measured variables.

18. The method according to claim 16, wherein the electrical characteristic variable is compared to a threshold value which includes a nominal resistance, and, in the event of a significant deviation, error information is generated.

19. The method according to claim 16, wherein the measured variable is supplied to a parameter estimator, wherein the characteristic variable is constantly updated by the parameter estimator in the presence of a new measured variable.

20. The method according to claim 18, wherein the threshold value is selected variably, using a thermal resistance model.

21. The method according to claim 18, wherein a temperature of at least one of the current-carrying components is sensed and/or used for ascertaining the threshold value.

22. The method according to claim 19, wherein the parameter estimator is used to recursively solve an equation system U=I*R, where U is a voltage drop at at least one of the current-carrying components, I is a measure of a current flowing through at least one of the components, and R is the electrical characteristic variable, to ascertain the electrical characteristic variable.

23. The method according to claim 19, wherein the parameter estimator includes comprises at least one prediction and/or one correction of systematic measurement errors of the measured variable.

24. The method according to claim 16, wherein, for offset compensation of the electrical characteristic variable, an estimated value (\hat{b}₁) of a constant superimposed variable is ascertained, using the following formula:
$$U = ( a 1 * I + b 1 ) * R = a 1 * I * R + ( b 1 * R ) , where b 1 * R = {\hat{b}}_{1} ,$$
where U is a voltage drop at at least one of the current-carrying components, I is a measure of current flowing through at least one of the current-carrying components, a1 is an amplification factor, and R is the electrical characteristic variable.

25. The method according to claim 24, wherein a measuring resistor arranged upstream of a branching into at least two parallel paths is used to sense the measure of the current flowing through the at least one of the current-carrying components, and/or a measuring amplifier including a differential amplifier is used to sense the measure of the voltage dropping at the at least one of the current-carrying components.

26. The method according to claim 16, wherein a semiconductor switch and/or a fuse are used as the current-carrying components.

27. The method according to claim 16, wherein at least one measuring point for sensing a measure of current and/or voltage of both the at least one of the current-carrying components and a supply line, is arranged at a start and/or at an end of the supply line.

28. The method according to claim 16, wherein a measuring point for voltage measurement and/or current measurement is arranged at at least one contact of the control unit.

29. The method according to claim 16, wherein when the measured value lacks currentness, a load pulse is requested for a current sensing of the measured value.

30. The method according to claim 16, wherein the supply path is arranged between an on-board power subsystem for at least one safety-relevant consumer and a further on-board power subsystem for at least one non-safety-relevant consumer.
